(19) United States
(12) Patent Application Publication
(10) Pub. No.: US 2012/0194049 A1
(43) Pub. Date: Aug. 2, 2012

(54) CABINETS FOR STORING ELECTRONIC APPARATUS

(75) Inventor: Michael Charles Alfred Cook, Bedfordshire (GB)

(73) Assignee: USYSTEMS LIMITED, Bedfordshire (GB)

(21) Appl. No.: 13/387,004

(22) PCT Filed: Jul. 20, 2010
(86) PCT No.: PCT/GB2010/051187

§ 371 Date: Apr. 4, 2012

(30) Foreign Application Priority Data
Jul. 30, 2009 (GB) 0913268.9
Dec. 4, 2009 (GB) 0921307.5

(51) Int. Cl. H05K 5/02; H05K 7/20

(52) U.S. Cl. 312/236; 312/294; 312/330.1; 312/333; 312/326

(57) ABSTRACT

The present invention provides a cabinet for housing electronic equipment, the cabinet comprising two generally parallel side walls and a door moveable between a closed position and a fully open position; wherein the distance between the door and each of the side panels is greater when the door is in the fully open position than the distance between the door and each of the side panels when the door is in the closed position, and also wherein the orientation of the door with respect to the plane of each of the side doors is generally the same in the fully open position as it is in the closed position.

The present invention relates to cabinets for housing electronic apparatus, particularly cabinets allowing more efficient storage of equipment in data centres or computer rooms.

In recent years the amount of electrical equipment used in offices has increased dramatically, and it has become common practice to house such equipment, particularly data processing and telecommunications equipment, in standardised racks, which may themselves be housed in purpose built enclosures or cabinets. Various standards for such racks and cabinets have developed, so that cabinets from different sources are normally compatible with electrical equipment from a wide range of manufacturers. One widely adopted standard for electrical equipment is known as the “19 inch rack” or “19 inch rack enclosure”, in which most conventional telecommunications or data processing equipment may be stored. In this field the terms “rack”, “enclosure” and “cabinet” are often used interchangeably.

It has also become common practice to store large amounts of electrical equipment in dedicated locations, sometimes known as data centres, data farms or computer rooms, and in such rooms the electrical equipment is generally housed in cabinets, which are arranged in rows with aisles between, permitting access to the front and back of each cabinet. Heat generation by electrical equipment housed in such cabinets previously required the cabinets to be arranged with large amounts of space between each row, which in turn required a large amount of floor space for storing the equipment. Improvements in cooling systems, both integral to the equipment/cabinets (for example as disclosed in U.S. Pat. No. 7,385,810), and in the storage rooms themselves, has partially reduced the amount of clearance required between rows of cabinets, however other factors still limit the degree to which the space between rows of cabinets may be reduced.

Cabinets for housing electronic equipment generally include doors allowing access to the interior of the cabinet from the front and/or the rear of the cabinet, and this may be particularly important when cooling means are incorporated into cabinets, particularly in the doors of the cabinets. However, health and safety provisions often require that there must be sufficient space between rows of cabinets for ease of movement between the rows of cabinets even when one or more of the doors of the cabinets in the rows are open (for example in emergency situations, when rapid evacuation of the storage room is required). Thus, the current minimum spacing possible between rows of cabinets is equivalent to the space occupied by an open door of a cabinet (and possibly also an opposing door of the facing cabinet) plus an additional space for movement between the open doors. A minimum spacing between rows of 1200 mm is often specified.

The present invention provides a cabinet for housing electronic equipment, the cabinet comprising two generally parallel side walls and a door moveable between a closed position and a fully open position; wherein the distance between the door and each of the side panels is greater when the door is in the fully open position than the distance between the door and each of the side panels when the door is in the closed position, and also wherein the orientation of the door with respect to the plane of each of the side doors is generally the same in the fully open position as it is in the closed position.

Cabinets according to the present invention permit the more efficient use of space in data centres or computer rooms, because rows of the cabinets may be positioned closer together than rows of conventional cabinets, as the opening of at least one of the doors of the cabinets does not hinder passage through the corridor between rows of the cabinets, thereby allowing the spacing between the cabinets to be reduced.

In cabinets according to the present invention, the door preferably contacts an edge of each of the two side walls in the closed position. It will be apparent however that, if necessary, a seal, or sealing material, may be provided between the door and the edges of the side walls to improve the closure between the door and the edges of the side walls.

In cabinets of the present invention, the door is preferably an equal distance from each side wall in the fully open position. Most preferably, the door will remain in a fixed orientation with respect to the planes of the side walls during opening, so that at any point between the closed position and the fully open position the linear distance of the door from one side wall will be the same as the linear distance of the door from the other side wall.

Preferably, cabinets according to the present invention are constructed so that the door is generally perpendicular to the planes of each of the side walls in both the fully open and the closed positions. More preferably, the door of the cabinet opens in such a way that it will remain perpendicular to the plane of each of the side walls at any position between the closed position and the fully open position.

In cabinets according to the present invention, the door is preferably connected to the main body of the cabinet by one or more struts which slidably engage receiving means positioned on the main body of the cabinet. Preferably, the receiving means are positioned on, or near to, the top of the cabinet, for example in the upper surface of the cabinet or on top of the upper surface of the cabinet. Most preferably no other links are present between the door and the main body of the cabinet.

In cabinets according to the present invention wherein the door is connected to the main body of the cabinet by one or more struts, the receiving means slidably engaged by the struts are preferably orientated so as to be parallel to the planes of the two side walls.

Most preferably, in cabinets of the present invention, the door is connected to the main body of the cabinet by two or more struts, each strut slidably engaging a separate receiving means positioned on the main body of the cabinet.

Any conventional combinations of struts and receiving means may be used in cabinets of the present invention. For example, the receiving means may simply comprise tubes into which the struts slide, or additional means to assist movement of the slides within the receiving means may be provided (for example low friction surfaces, rollers or the like). The struts and receiving means may also be made from any conventional materials including metals, plastics and wood, and each component may be made of the same or different materials.

Optionally, in cabinets of the present invention wherein the door is connected to the cabinet by two or more struts, one end of each strut may be pivotally connected to the door, and the other end of each strut may be pivotally connected to the main body of the cabinet, so that when the door is in the fully open position the door may be moved laterally with respect to the main body of the cabinet by rotation round each pivot point. It will be appreciated that in this optional arrangement, as each end of each strut is pivotally connected either to the door or to the main body of the cabinet, when the door is in the fully open position it may be moved sideways by rotation around each pivotal connection, but the orientation of the door with respect to the plane of each of the side walls will remain constant. This arrangement provides further flexibility for the positioning of the door of the cabinet, and can provide improved access to the interior of the cabinet and/or the door.

In an alternative arrangement, cabinets according to the present invention may be constructed so that the door is suspended from a location above the cabinet, preferably from the ceiling of the room in which the cabinet is housed. In this arrangement, the door may be connected to the location above the cabinet by any means, including one or more rods, chains, straps or other supporting means. Preferably, in this arrangement the location above the cabinet is provided with means to assist movement of each support for the door, for example tracks may be fitted in the ceiling above the cabinet so that the door may be opened by sliding each connecting means along the tracks. In this arrangement, it is preferable that there is no direct connection between the door and the main body of the cabinet when the door is in the fully open position.

Preferably cabinets according to the present invention comprise wheeling or sliding means located on the bottom surface of the door. The wheeling or sliding means will assist in movement of the door between the closed and fully open positions. Suitable wheeling or sliding means comprise one or more rollers, wheels, castors, low friction materials or the like.

Preferably, cabinets according to the present invention comprise means to lock the door in the closed position. Such means may comprise any conventional locking means to prevent accidental or unauthorised opening of the cabinets.

Cabinets according to the present invention preferably comprise means to fix the door in the fully open position. Such means may comprise any conventional means to prevent accidental closure of the door during inspection of the contents of the cabinet. Such means may include means for fixing the door in contact with the supporting floor, or braking means preventing movement of the door with respect to the body of the cabinet.

Cabinets according to the present invention comprising means to fix the door in the closed and/or fully open position may also comprise means to fix the door in one or more partially open positions, preferably at any position between the closed and fully open positions. Such means may comprise any conventional means for preventing movement of the door with respect to the main body of the cabinet.

In preferred cabinets according to the present invention, the door comprises means to cool the interior of the cabinet and/or air exiting the cabinet through the door. Any conventional means for cooling the interior of the cabinet and/or the air exiting the cabinet through the door may be used, for example heat exchange assemblies may be incorporated into the door, which may also incorporate means to allow air to pass into and out of the door from the interior of the cabinet to the exterior. Examples of suitable cooling means include those disclosed in U.S. Pat. No. 7,385,810 and the ColdLogik (™) systems available from USystems Limited.

Preferably, cabinets according to the present invention comprise two doors located on opposing faces of the cabinets. In a first embodiment, one of the doors may be a door as described hereinbefore whilst the other door is a conventional door hingedly mounted along one edge of the cabinet. In a second, preferred, embodiment however, both doors are doors as described hereinabove, most preferably at least one of the doors comprising means for cooling the interior of the cabinet and/or air exiting the cabinet through the door.

Cabinets according to the present invention may be any size or shape suitable for housing electronic equipment. Preferably however, the cabinets are compatible with industry standards, for example the 19 inch rack standard.

Cabinets according to the present invention may be made from any suitable materials including wood, aluminium or steel, or combinations thereof. As an example, a basic substructure may be manufactured from mild steel, and surface panels of wood or wood composite may be attached thereto.

Cabinets according to the present invention may also comprise any conventional noise reducing means, including passive or active noise reduction systems and/or noise absorbing materials.

Cabinets according to the present invention are suitable for storing any electronic equipment, particularly data processing or telecommunications equipment.

Embodiment of the present invention will now be described by way of example, by reference to the following drawings in which:

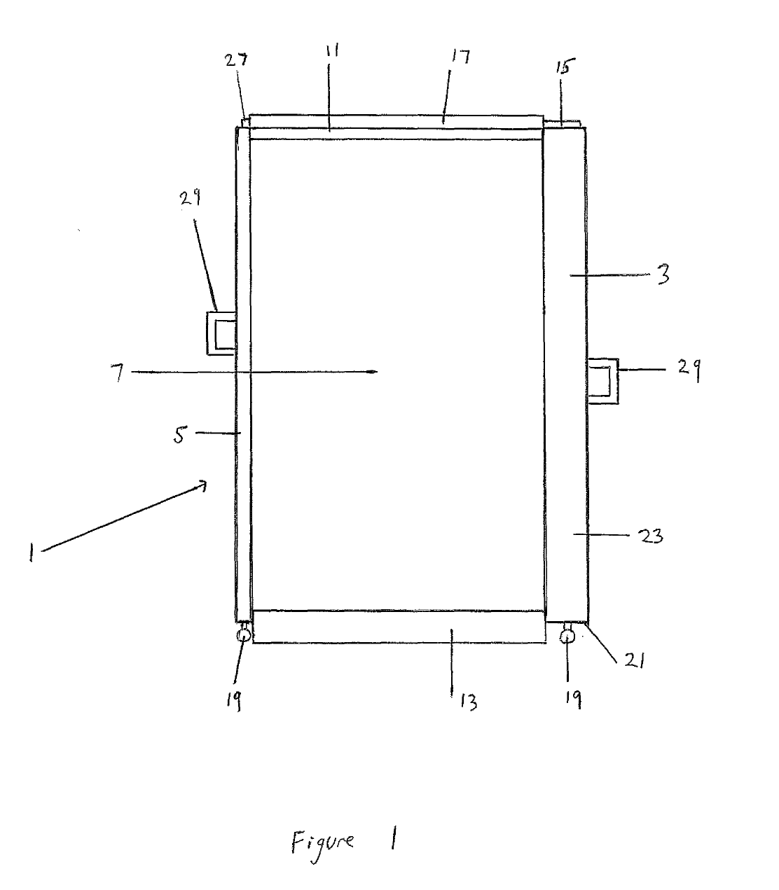

FIG. 1 is a side view of a first embodiment of a cabinet of the present invention having two doors, each of the doors being shown in the closed position;

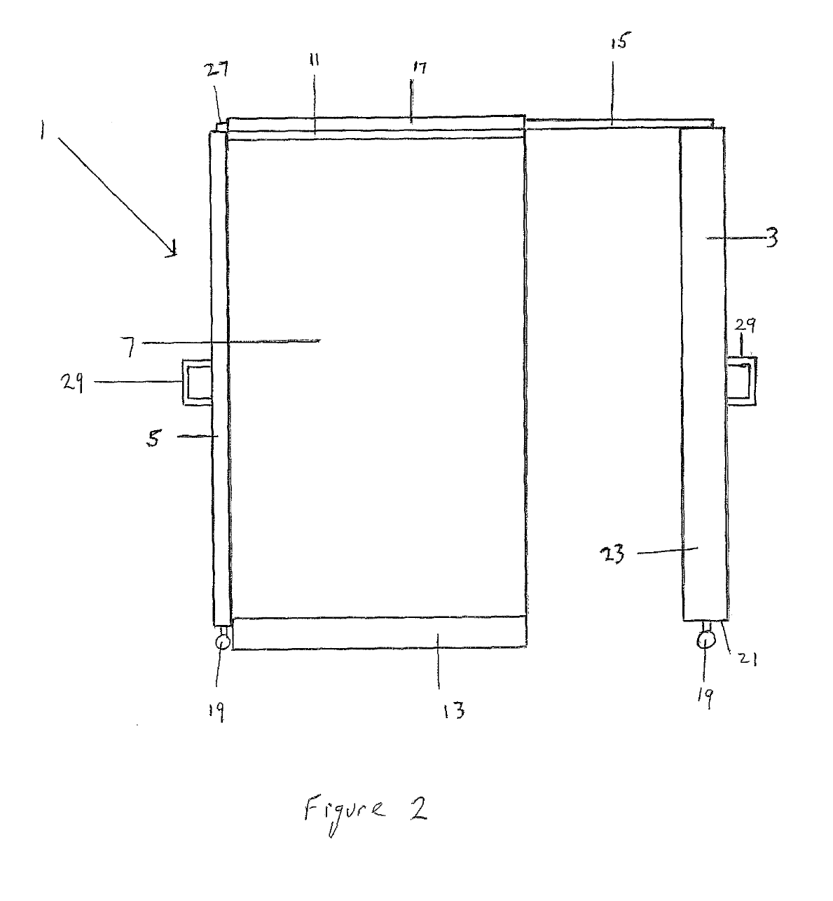

FIG. 2 is a side view of the cabinet shown in FIG. 1 with one of the doors shown in the fully open position,

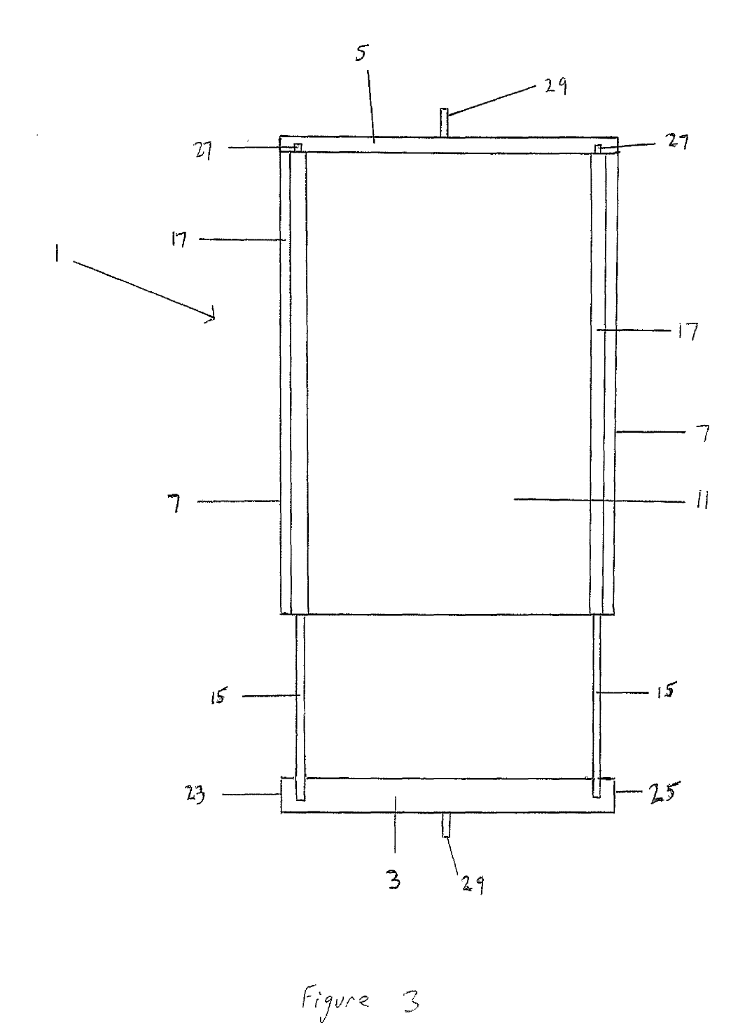

FIG. 3 is a plan view of the cabinet shown in FIGS. 1 and 2 with one of the doors shown in the fully open position,

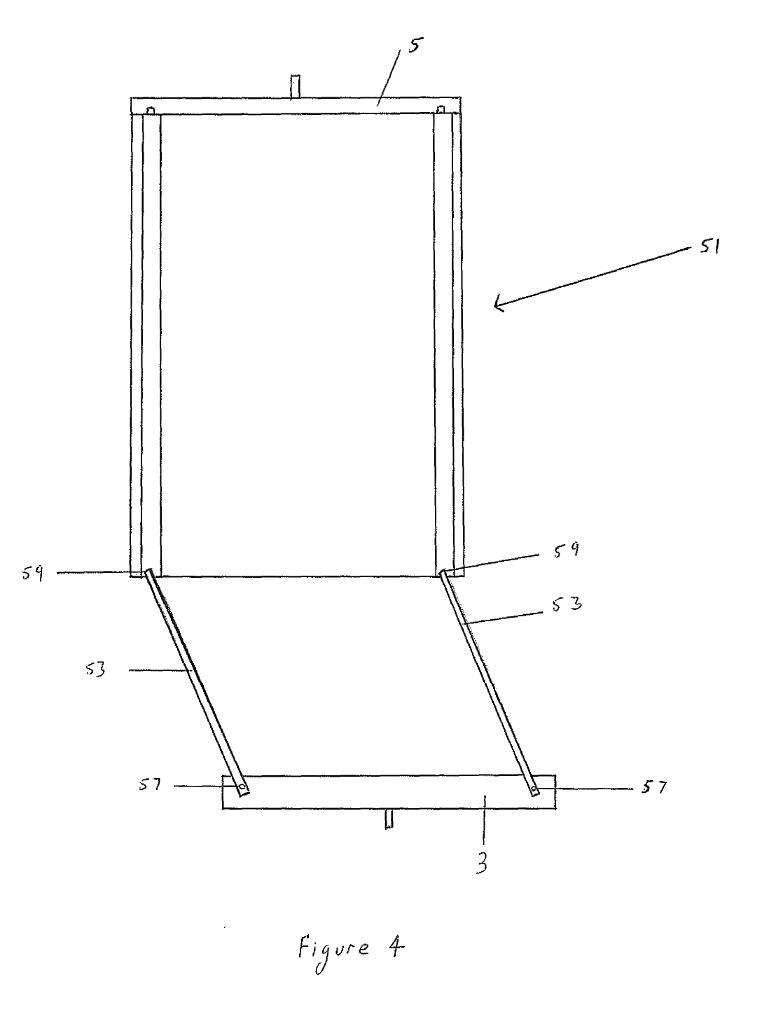

FIG. 4 is a plan view of a second embodiment of a cabinet of the present invention having two doors, with one of the doors shown in the fully opened position, and

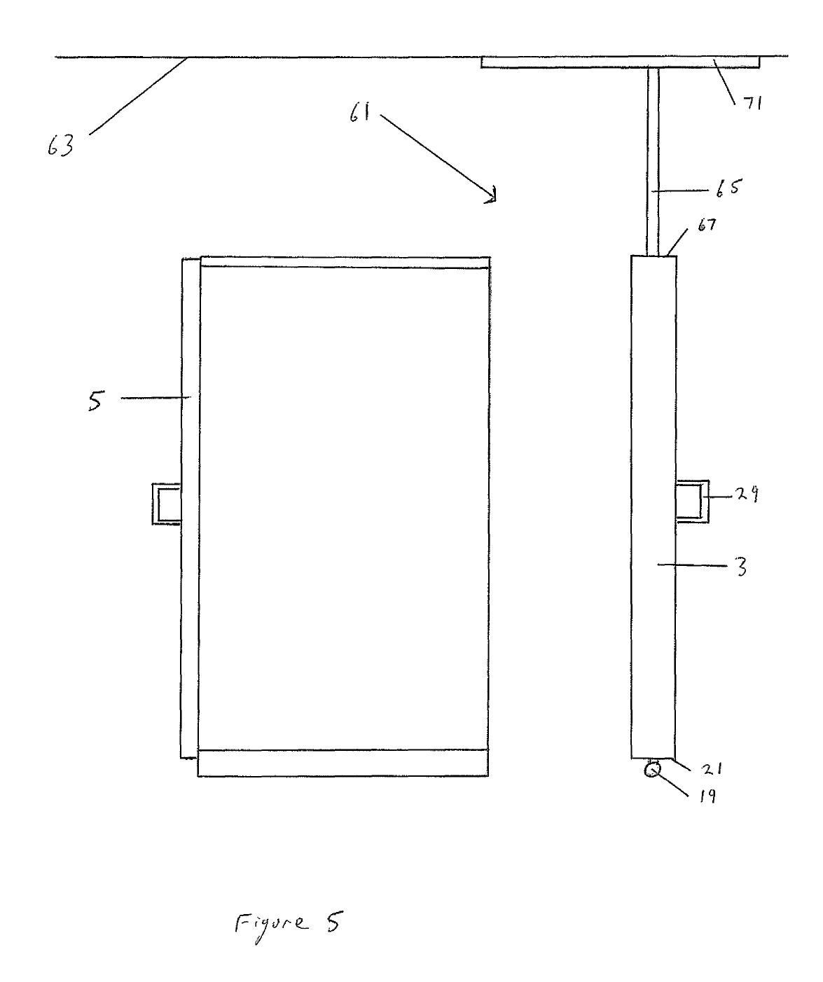

FIG. 5 is a side view of a third embodiment of a cabinet of the present invention having two doors, with one of the doors shown in a partially open position.

FIG. 1 shows a side view of a first embodiment of a cabinet 1 of the present invention. The cabinet 1 comprises a rear door 3, and a front door 5. Both of the doors 3, 5 are shown in the closed position in FIG. 1.

The cabinet 1 comprises two parallel side walls 7 connected by an upper surface 11 and a lower surface 13. As shown in FIG. 1, the rear door 3 and the front door 5 effectively seal the cabinet 1 when they are both closed.

As shown more clearly in FIGS. 2 and 3, the rear door of the cabinet 3 is connected to the main body of the cabinet 1 by two struts 15 which are permanently attached to the rear door 3. The struts 15 are each received within tubes 17 located on the upper surface 11 of the cabinet 1 adjacent to, and parallel with, the side walls 7. The struts 15 engage the tubes 17 and slide therein.

The rear door 3 also comprises rollers 19 positioned on the bottom edge 21 thereof. Two rollers 19 are attached to the bottom edge 21 of the rear door 3, one roller being positioned adjacent to the first side edge 23 of the door, and the other roller 19 being positioned adjacent to the second side edge 25 of the rear door 3. In alternative embodiments, additional rollers 19 may be included at other positions along the bottom edge 21 of the rear door 3, or the two rollers 19 may be replaced by a single roller 19 positioned at or adjacent to the centre of the bottom edge 21 of the rear door 3. Alternatively, the rollers 19 may be replaced by other conventional wheeling means, or any other means permitting the rear door 3 to slide across the supporting surface on which the cabinet 1 is placed, for example blocks of low friction materials.

The rear door 3 is orientated perpendicularly to the planes of the side walls 7 in the closed position, and will remain at this orientation as it is moved from the closed position to the fully open position, as shown in FIG. 3. The rear door 3 may be opened to any convenient distance from the main body of the cabinet 1 so as to permit access to the interior of the cabinet 1. As shown in FIG. 2, when the rear door 3 is fully open it obstructs only a minimal amount of the space surrounding the cabinet 1, and when cabinets according to the first embodiment of the invention shown in FIGS. 1 to 3 are stored in rows with their side walls 7 adjacent, movement between the rows of the cabinets 1 will not be restricted when the rear doors 3 are open.

The rear door 3 of the cabinet 1 shown in FIGS. 1 to 3 incorporates conventional means for cooling air exiting the cabinet through the rear door 3. These means include cooled heat exchanger coils and means for air to pass from the interior of the cabinet 1 through the door 3 and into the surrounding environment. Preferably the cabinet comprises a ColdLogik (™) rear door cooling system available from USystems Limited.

The front door 5 of the cabinet 1 shown in FIGS. 1 to 3 is also connected to the main body of the cabinet 1 by struts 27, and includes one or more rollers 19 to assist in the opening of the door. In the embodiment shown in FIGS. 1 to 3, the struts 27 of the front door 5 are received in the tubes 17 which also receive the struts 15 of the rear door 3. However, it will be appreciated that in an alternative embodiment the struts 27 of the front door 5 could be received in separate tubes positioned on the upper surface 11 of the cabinet. In a further alternative, the struts 15 of the rear door 3 and/or the struts 27 of the front door 5, could be received either in tubes located beneath the upper surface 11 of the cabinet 1 (attached either to the underside of the upper surface 11 or to the side walls 7) or directly in cavities located within the upper surface 11 or the side walls 7 of the cabinet 1.

In an alternative embodiment, the front door 5 of the cabinet 1 could be replaced by a conventional door hingedly attached to one of the side walls 7 of the cabinet 1.

The first embodiment of a cabinet 1 of the present invention shown in FIGS. 1 to 3 is suitable for housing electronic equipment, particularly data processing or telecommunications equipment, and is compatible with the 19 inch rack standard. The cabinet 1 is constructed from mild steel, but in an alternative embodiment it could be constructed from wood, aluminium or mixtures thereof, for example a steel sub-frame with wood panels attached.

The first embodiment of a cabinet 1 of the present invention shown in FIGS. 1 to 3 comprises means to prevent unauthorised opening of the rear door 3, in the form of conventional locks. The cabinet 1 also comprises brakes attached to the rollers 19 of the rear door 3, which may be activated to prevent movement of the rear door 3 when it is in a selected open position. The rear door 3 and the front door 5 also both comprise handles 29 to assist in opening the doors 3, 5.

The first embodiment of a cabinet 1 according to the present invention shown in FIGS. 1 to 3 may comprise conventional noise reduction means, including sound absorbing materials.

A second embodiment of a cabinet 51 according to the present invention is shown in FIG. 4. The second embodiment of a cabinet 51 of the present invention shown in FIG. 4 generally corresponds to the first embodiment of a cabinet 1 of the present invention shown in FIGS. 1 to 3, and parts of the second embodiment of a cabinet 51 that are identical to parts of the first embodiment of a cabinet 1 are shown with identical numbering. The second embodiment of a cabinet 51 differs from the first embodiment of a cabinet 1, in that each of the two struts 53 connecting the door 3 to the main body of the cabinet 51 comprise first pivotal connections 57 where the struts 53 attach to the door 3, and second pivotal connections 59 at the ends of the struts 53 connected to the main body of the cabinet 51. As will be seen from FIG. 4 therefore, once the door 3 is in the fully open position, the struts 53 may pivot around the first and second pivotal connections 57, 59 so that the door 3 may be moved laterally with respect to the main body of the cabinet 51. Any conventional means may be used to pivotally connect the struts 53 to the door 3 and the main body of the cabinet 51.

In the second embodiment of a cabinet 51 according to the present invention shown in FIG. 4, access to the interior of the cabinet 51 and/or to the door 3 can be improved by moving the door 3 laterally with respect to the body of the cabinet 51.

The second embodiment of a cabinet 51 according to the present invention shown in FIG. 4 is provided with a second door 5 at the front of the cabinet 51. The second door 5 may be connected to the cabinet 51 in the same manner as the first door 3, or it may be connected in the same manner as the doors 3, 5 of the first embodiment of a cabinet 1 shown in FIGS. 1 to 3. Alternatively, the second door 5 may be a conventionally attached hinged door 5.

A third embodiment of a cabinet 61 according to the present invention is shown in FIG. 5. The third embodiment of a cabinet 61 according to the present invention shown in FIG. 5 generally corresponds to the first embodiment of a cabinet 1 according to the present invention shown in FIGS. 1 to 3, and parts that are generally similar in both embodiments of the cabinets 1, 61 are numbered in common.

As will be seen from FIG. 5, the third embodiment of a cabinet 61 according to the present invention comprises a door 3 which is not directly connected to the main body of the cabinet 61. Instead, the door 3 is suspended from the ceiling 63 of the room in which the cabinet 61 is housed. The door 3 is connected to the ceiling 63 by two support chains 65. Each support chain 65 being attached at one end to the upper surface 67 of the door 3, one support chain 65 being attached at or towards one end of the upper surface 67 of the door 3, and the other support chain 65 being attached at or towards the other end of the upper surface 67 of the door 3; and being attached at the other end to the ceiling 63 via two generally parallel tracks 71, one support chain 65 being attached to one track 71, and the other support chain 65 being attached to the other track 71. In use, the door 3 of the third embodiment of a cabinet 61 according to the present invention may by opened by pulling on the handle 29, which causes the door 3 to move away from the body of the cabinet 61, the weight of the door 3 being carried by the support chains 65. Further support for the door 3 is also provided by rollers 19 located along the bottom edge 21 of the door 3. The door 3 may be opened to any distance from the body of the cabinet 61, depending upon the length of the track 71. Means to assist movement of the support chain 65 in the track 71 may be provided, for example in the form of remotely activatable electrical motors.

The third embodiment of a cabinet 61 according to the present invention shown in FIG. 5 may be provided with a second door 5 on the face of the cabinet opposite to the rear door 3. The second door 5 may also be suspended from the ceiling 63, or may be connected to the main body of the cabinet 61 in the manner of the doors 3 of the first and second embodiments of a cabinet 1, 51 according to the present invention shown in FIGS. 1 to 4. Alternatively, the second door 5 may be a conventionally attached hinged door.

The second and third embodiments of cabinets 51, 61 of the present invention shown in FIGS. 4 and 5 are suitable for housing electronic equipment, as discussed for the first embodiment of the cabinet 1 of the present invention shown in FIGS. 1 to 3. The second and third embodiments of the cabinets 51, 61 of the present invention shown in FIGS. 4 to 5 may also comprise one or more means to prevent unauthorised opening of the rear door 3, and/or conventional noise reduction means, as discussed with respect to the first embodiment of the cabinet 1 of the present invention shown in FIGS. 1 to 3.

1. A cabinet for housing electronic equipment, the cabinet comprising two generally parallel side walls and a door moveable between a closed position and a fully open position; wherein the distance between the door and each of the side panels is greater when the door is in the fully open position than the distance between the door and each of the side panels when the door is in the closed position, and also wherein the orientation of the door with respect to the plane of each of the side doors is generally the same in the fully open position as it is in the closed position.

2. A cabinet as claimed in claim 1, wherein the door contacts an edge of each of the two side walls in the closed position.

3. A cabinet as claimed in claim 1, wherein the door is an equal distance from each side wall in the fully open position.

4. A cabinet as claimed in claim 1, wherein the door is generally perpendicular to the planes of each of the side walls in both the fully open and the closed positions.

5. A cabinet as claimed in claim 1, wherein the door is connected to the main body of the cabinet by one or more struts which slidably engage receiving means positioned on the main body of the cabinet.

6. A cabinet as claimed in claim 5, wherein the receiving means are positioned on or near to the top of the cabinet.

7. A cabinet as claimed in claim 5, wherein the receiving means are orientated so as to be parallel to the planes of the two side walls.

8. A cabinet as claimed in claim 5, wherein the door is connected to the main body of the cabinet by two or more struts, each strut slidably engaging a separate receiving means positioned on the main body of the cabinet.

9. A cabinet as claimed in claim 5 wherein the door is connected to the main body of the cabinet by two or more struts, one end of each strut being pivotally connected to the door, and the other end of each strut being pivotally connected to the main body of the cabinet, so that when the door is in the fully open position the door may be moved laterally with respect to the main body of the cabinet.

10. A cabinet as claimed in claim 1, wherein the door is suspended from a location above the cabinet.

11. A cabinet as claimed in claim 10, wherein the door is suspended from the ceiling of the room in which the cabinet is installed.

12. A cabinet as claimed in claim 10, wherein there is no direct connection between the door and the main body of the cabinet when the door is in the fully open position

13. A cabinet as claimed in claim 1, wherein the door comprises wheeling or sliding means located on the bottom surface thereof

14. A cabinet as claimed in claim 13, wherein the wheeling or sliding means comprise one or more rollers, wheels, castors or low friction materials.

15. A cabinet as claimed in claim 1, comprising means to lock the door in the closed position.

16. A cabinet as claimed in claim 1, further comprising means to fix the door in the fully open position.

17. A cabinet as claimed in claim 16, further comprising means to fix the door in one or more partially open positions.

18. A cabinet as claimed in claim 1, wherein the door comprises means to cool the interior of the cabinet and/or air exiting the cabinet through the door.

19. A cabinet as claimed in claim 1, further comprising two doors located on opposing faces of the cabinet.

20. A cabinet as claimed in claim 19, wherein one door is a door as described in claim 1 and one door is hingedly mounted along one edge of the cabinet.

21. A cabinet as claimed in claim 19, wherein both doors are doors as described in claim 1.

22. A cabinet as claimed in claim 1 which is compatible with the 19 inch rack standard.

23. A cabinet as claimed in claim 1 for housing data processing or telecommunications equipment.

24. (canceled)
